(19) United States
(12) Patent Application Publication
(10) Pub. No.: US 2026/0311953 A1
(43) Pub. Date: Oct. 8, 2026

(54) PROCESSING SYSTEM FOR GENERATING ION BEAMS HAVING TUNABLE ANGLE

(71) Applicant: Applied Materials, Inc., Santa Clara, CA (US)

(72) Inventors: Costel Biloiu, Rockport, MA (US); Tyler Rockwell, Wakefield, MA (US); David Morrell, Wakefield, MA (US); Kevin M. Daniels, Lynnfield, MA (US); Christopher Campbell, Newburyport, MA (US)

(73) Assignee: Applied Materials, Inc., Santa Clara, CA (US)

(21) Appl. No.: 19/172,909

(22) Filed: Apr. 8, 2025

(51) Int. Cl. H01J 37/08

(52) U.S. Cl. CPC H01J 37/08; H01J 2237/032; H01J 2237/036; H01J 2237/038; H01J 2237/061

(57) ABSTRACT

A processing apparatus may include a plasma chamber and an ion extraction optics, disposed on a side of the plasma chamber. The processing apparatus may further include a processing chamber, having a substrate holder, disposed opposite the ion extraction optics. The ion extraction optics may include an extraction plate, connected to the plasma chamber, and having an extraction aperture. The extraction optics may also include a beam blocker disposed adjacent to the extraction aperture, so as to define a set of extraction slits between the beam blocker and the extraction plate, and an electrode array, disposed along the beam blocker, and comprising a plurality of electrodes that are separately connectable to a voltage source.

### FIELD OF THE DISCLOSURE

The disclosure relates generally to processing apparatus, and more particularly to plasma based ion sources for generating angled ion beams.

### BACKGROUND OF THE DISCLOSURE

In the present day, plasmas are used to process substrates, such as electronic devices, for applications such as substrate etching, layer deposition, ion implantation, and other processes. Some processing apparatus employ a plasma chamber that generates a plasma to act as an ion source for substrate processing. An ion beam may be extracted through an extraction assembly and directed to a substrate in an adjacent chamber. This plasma may be generated in various ways.

Compact ion beam apparatus may include, for example, an extraction plate with an elongated extraction aperture to extract elongated ion beams for processing a substrate. The substrate may be scanned under an elongated ion beam, often referred to as a ribbon beam, such that the entire substrate is exposed to the ribbon beam in a sequential fashion. A structure that may be referred to as a beam blocker may be provided next to the extraction aperture to define narrow slits that generate an angled ion beam that impinges on the substrate at a given angle of incidence with respect to a normal to the main plane of the substrate.

Depending upon the application, a desired angle of incidence for treating a substrate may vary. Thus, the design of an extraction system including extraction plate and beam blocker may take into account the desired beam angle of incidence for the given application. However, present day extraction system designs may have limited flexibility to address different applications, requiring different angles of incidence.

With respect to these and other considerations the present disclosure is provided.

### BRIEF SUMMARY

In one embodiment a processing apparatus is provided. The processing apparatus may include a plasma chamber and an ion extraction optics, disposed on a side of the plasma chamber. The processing apparatus may further include a processing chamber, having a substrate holder, disposed opposite the ion extraction optics. The ion extraction optics may include an extraction plate, connected to the plasma chamber, and having an extraction aperture. The extraction optics may also include a beam blocker disposed adjacent to the extraction aperture, so as to define a set of extraction slits between the beam blocker and the extraction plate, and an electrode array, disposed along the beam blocker, and comprising a plurality of electrodes that are separately connectable to a voltage source.

In another embodiment, an ion extraction optics for a processing apparatus is provided. The ion extraction optics may include an extraction plate, having an extraction aperture that is elongated along a first direction. The ion extraction optics may further include a beam blocker, attachable to the extraction plate, in a region adjacent to the extraction aperture, so as to define a set of extraction slits that extend between the beam blocker and extraction plate, and an electrode array, comprising a plurality of electrodes that are disposed along the beam blocker, and are separately connectable to a voltage source.

### BRIEF DESCRIPTION OF THE DRAWINGS

FIG. 1A shows a side view of a processing system, according to embodiments of the disclosure;

FIG. 1B shows an enlarged view of an ion extraction optics of the processing system of FIG. 1A;

FIG. 1C shows a cross-sectional view of an exemplary scenario for operating the ion extraction optics of FIG. 1A;

FIG. 2A, FIG. 2B, and FIG. 2C, show in side cross-sectional view three different scenarios for operating a variant of the ion extraction optics of FIG. 1A;

FIG. 3 provides a graph that depicts the current density of an ion beam near the substrate position as a function of angle of incidence with respect to a perpendicular to plane of the substrate, a graph that roughly represents Ion Angular Distribution (IAD) at the plane of the substrate, based upon the geometry of FIGS. 2A-2C;

FIG. 4A, FIG. 4B, FIG. 4C, and FIG. 4D show in side cross-sectional view four different scenarios for operating a variant of the ion extraction optics of FIG. 1B;

FIG. 5 provides a graph that depicts the current density of an ion beam near the substrate position as a function of angle of incidence with respect to the perpendicular to plane of the substrate, based upon the geometry of FIGS. 4A-4D;

FIG. 6A, FIG. 6B, FIG. 6C, and FIG. 6D show in side cross-sectional view five different scenarios for operating an exemplary ion extraction optics;

FIG. 7 provides a graph that depicts the current density of an ion beam near the substrate position as a function of angle of incidence with respect to the perpendicular to plane of the substrate, based upon the geometry of FIGS. 6A-6D;

FIG. 8 shows a graph that depicts the current density of an ion beam near the substrate position as a function of angle of incidence with respect to the perpendicular to plane of the substrate, based upon an exemplary ion extraction optics for two different scenarios of operation;

FIG. 9A and FIG. 9B show in side cross-sectional view two different scenarios for operating a variant of an ion extraction optics;

FIG. 10A shows a graph that depicts the current density of an ion beam near the substrate position as a function of angle of incidence, for an operation scenario as applied to two different exemplary extraction assemblies;

FIG. 10B shows a graph that depicts the current density of an ion beam near the substrate position as a function of angle of incidence, for another operation scenario as applied to the two different exemplary extraction assemblies of FIG. 10A;

FIG. 11A, FIG. 11B, FIG. 11C, FIG. 11D, and FIG. 11E show differing views of a beam blocker, arranged according to embodiments of the disclosure;

FIG. 12A and FIG. 12B show an isometric end cross-sectional view of two variants of a beam blocker 300;

FIG. 13A, FIG. 13B and FIG. 13C depict different embodiments, where a component of an extraction plate is biased with respect to the substrate, in addition to the electrode array provided in a beam blocker; and

FIG. 14 a graph that depicts the current density of an ion beam near the substrate position as a function of angle of incidence with respect to the perpendicular to plane of the substrate, based upon the different extraction assemblies represented by FIG. 13A, FIG. 13B, and FIG. 13C.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are apparatus and systems to process substrates using angled ion beams. An ion extraction optics is included that provides the capability of in-situ variation of the angle of incidence of an angled ion beam.

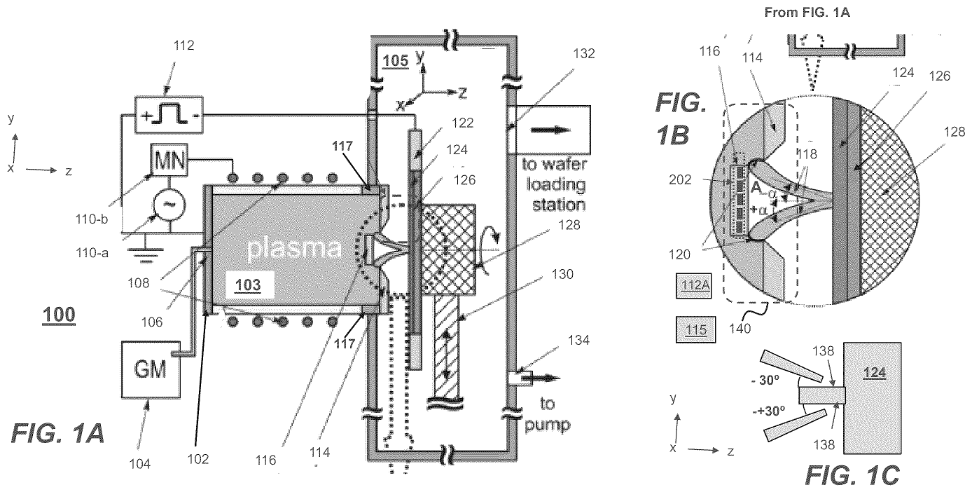

Turning to the figures, FIG. 1A shows a side view of a processing system, shown as system 100, including an ion source, referred to herein as a plasma chamber 102, that is supplied with the working gas mixture from a gas source 104. In various non-limiting embodiments, the plasma chamber 102 may function to generate an inductively coupled plasma (ICP), a capacitively coupled plasma, or any other suitable plasma therein, shown as plasma 103. For example, an applicator 108 (in this example a solenoidal rf antenna) may be provided to generate an ICP plasma, where the applicator is coupled to an RF generator 110-a via a matching network 110-b. An extraction plate 114 and a beam blocker 116 may be provided to extract an ion beam 118 as shown in the inset image of FIG. 1B. In this example, the ion beam 118 is extracted as a pair of symmetrical beamlets as shown.

A process chamber 105 is arranged adjacent to the plasma chamber 102, and houses a substrate platen 126 that supports a substrate 124. A halo structure 122 may be provided around the substrate 124. Additionally, the process chamber 105 may include a rotation stage 128 and translation stage 130 that are coupled to the substrate platen to provide rotational movement (for example, around the Z-axis of the Cartesian coordinate system shown, and translational movement (for example, along the Y-axis) to the substrate 124.

To extract a positive ion beam, shown as ion beam 118, an extraction voltage source 112 may be provided to couple to the plasma 103 through the plasma chamber 102 and substrate 124. In one example, the extraction voltage source 112 may provide a pulsed DC voltage between the plasma chamber 102, which chamber is held at ground potential, and substrate 124 which is biased at a suitable negative voltage that is generated to impart the desired ion energy of the ion beam 118, such as −100 V, −200 V, −500 V, −1 kV, −2 kV, −5kV, and so forth.

A pumping port 134 for pumping gas from the process chamber 105, and loading port 132, for loading substrate the 124, may also be included.

As shown in FIG. 1B, the extraction plate 114 includes an extraction aperture A. In some embodiments, the extraction aperture A may be elongated along the X-axis, so that the extraction aperture A appears as an elongated slot as viewed in the X-Y plane. Likewise, the beam blocker 116 may be elongated along the X-axis.

In some embodiments, the extraction plate 114 and the beam blocker 116 may be separated by a distance of few millimeters along z-axis. In particular non-limiting embodiments, the height (along the Y-axis) of the beam blocker 116 may be equal to the height of the extraction aperture A. Both the extraction plate 114 and the beam blocker may be made of dielectric material (such as alumina), where these components may be coated with a thin protection layer (not shown, such as few hundred micrometer-thick insulating layer that acts as a protective layer) made of a highly chemically resistant mixture of zirconium oxide and yttrium oxide. For this ion extraction optics, the extraction plate 114 may be made of metal coated with a protective dielectric layer. The extraction plate 114 can be biased at the substrate potential. In this case extraction plate is electrically insulated from the plasma chamber by an insulating spacer 117. In other embodiments an extraction plate may be made of dielectric material and have an embedded or printed metal electrode, which electrode can be biased at the substrate potential. In the case of a dielectric extraction plate there is no need for electrical insulation from the plasma chamber.

As shown in FIG. 1B, when extracted, the ion beam 118 may impinge upon the substrate 124 as an angled ion beam, characterized by a non-zero angle of incidence with respect to a perpendicular to a main plane of the substrate 124. In this case, the perpendicular is represented by the Z-axis and the main plane of the substrate 124 is represented by the X-Y plane. The non-zero angle of incidence is represented by a.

In some embodiments, the beam blocker 116 is arranged adjacent to the extraction aperture A in a manner to form two separate plasma menisci 120 at the edge of the plasma 103, so that ion beam 118 is extracted as two different beamlets, where these different beamlets may extracted to define opposing angles of incidence, shown as −α and +α. In particular, the beam blocker 116 may be arranged with respect to the extraction aperture A to split the ion beam 118 into two symmetrical beamlets, wherein the absolute values of −α and +α are equal to one another. Thus, in one example, the operational parameters of the system 100 may be set to generate two beamlets at angles of incidence of −30 degrees and +30 degrees with respect to the Z-axis.

In various embodiments where the extraction aperture A and beam blocker 116 are elongated along the X-axis, the ion beam 118 may be extracted as a pair of ‘ribbon’ beamlets that are elongated along the X-axis and impinge upon the substrate 124 at opposing and equal angles of incidence with respect to the Z-axis. This configuration may be useful to process the substrate 124, where features that are disposed on the substrate 124 are arranged in a suitable manner with respect to the ion beam 118. For example, structures such as pillars, trenches or other structures, may be aligned with opposing sidewalls oriented along the X-Z plane. The beamlets of ion beam 118 may then treat the opposing sidewalls 138 in an equal fashion, as shown in FIG. 1C.

In various embodiments, the extraction plate 114 and beam blocker 116 form an extraction assembly, referred to herein as ion extraction optics 140, that further includes an electrode array 202, where the function and structure of the electrode array 202, and similar arrays, is detailed with respect to the figures to follow. In brief, the electrode array 202 includes a plurality of electrodes, such as metal stripes, that are separately connectable to a voltage source. In this manner, a bias voltage may be applied to different electrodes of the electrode array 202, independently of one another.

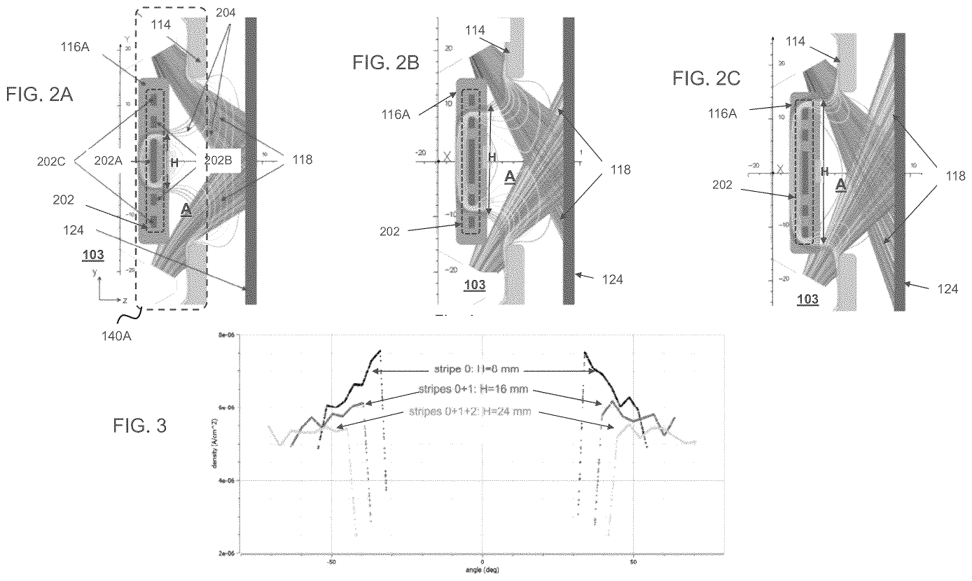

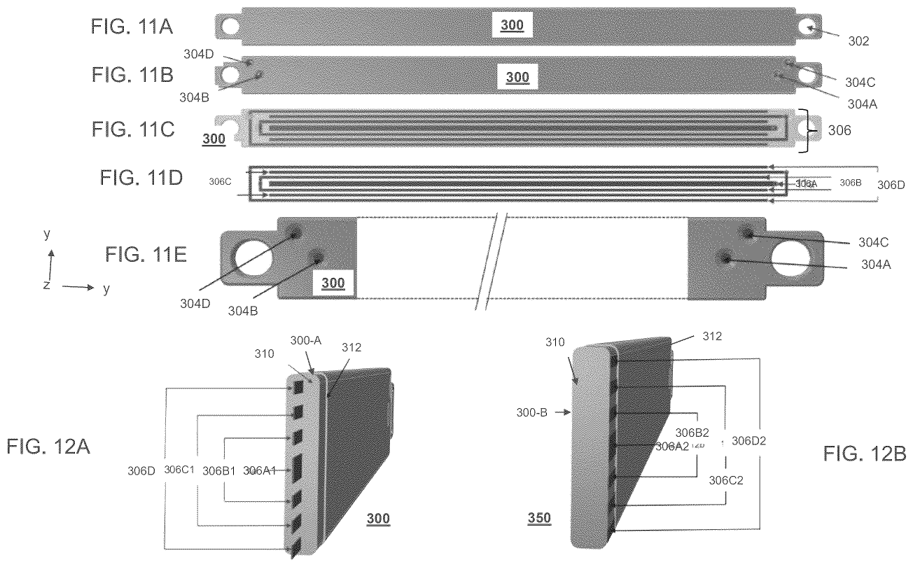

Turning now to FIG. 2A, FIG. 2B, and FIG. 2C, there are shown in side cross-sectional view three different scenarios for operating a variant of the ion extraction optics 140, shown as ion extraction optics 140A. In this embodiment, the electrode array 202 includes three separate electrodes, shown as electrode 202A, electrode 202B, and electrode 202C. Note that in this embodiment, the electrode 202B and electrode 202C may each be a continuous electrical stripe, as detailed further below with respect to FIG. 11C, and FIG. 11D, for example. In the embodiment particularly illustrated in FIGS. 2A-2C, the electrode 202A may be a central stripe, while the electrode 202B is an intermediate stripe, flanking both sides of electrode 202A, and the electrode 202C is an outer stripe, flanking the electrode 202B on both sides. In particular, in FIG. 2A, FIG. 2B, and FIG. 2C, there is shown the results of OPERA modelling, depicting distribution of equipotential lines 204 and extracted ion beamlets shape, indicated as ion beam 118, as a function of “electrostatic height” of the electrode array 202, for 1 kV biasing voltage, applied between substrate 124, extraction plate 114, and the electrode array 202 on one hand, and the plasma chamber 102 on the other hand. As shown, a plasma 103 is generated to the left of the ion extraction optics 140A in the figures. The extraction voltage between the plasma 103 contained by the plasma chamber 102 (see FIG. 1A) is also 1 kV, meaning the bias voltage between the plasma chamber 102 and substrate 124 is also 1 kV.

Turning to FIG. 2A, there is shown a scenario where just the electrode 202A is biased at 1 kV with respect to substrate 124, while electrode 202B and electrode 202C are not biased. In one example, the electrodes of electrode array 202, such as electrode 202A, may be biased with respect to substrate 124 by coupling to extraction voltage source 112. In other examples, the electrodes of electrode array 202 may be biased with respect to substrate 124 by coupling to an optional bias voltage source 112A, shown in FIG. 1B. The system 100 may include a controller 115 that is arranged to reversibly connect any combination of electrodes of electrode array 202 to the extraction voltage source 112 of to the optional bias voltage source 112A. For example, the controller 115 include or may be coupled to a set of switches that can connect and disconnect the different electrodes of electrode array 202 to an external bias voltage. In FIG. 2A, because just the electrode 202A is biased, the electrostatic height H of equipotential lines 204 along the Y-axis near the electrode array 202 is relatively less. In FIG. 2B, both the electrode 202A and electrode 202B are biased at 1 kV, generating a substantially greater value of the electrostatic height H, while in FIG. 2C electrode 202A, electrode 202B, and electrode 202C are all biased at 1 kV, generating a still greater value of electrostatic height H. As a result of changing the value of the electrostatic height H, the shape of ion beam 118, average angle of incidence and ion angular distribution (IAD) are changed between the configurations of FIG. 2A, FIG. 2B, and FIG. 2C, as qualitatively illustrated in the images of ion beam 118.

In one particular example, as represented in FIGS. 2A-2C, the electrode array 202 is formed of a central stripe of 8 mm height, represented by electrode 202A, a pair of first order neighboring stripes symmetrically distributed around the central stripe along Y-axis, represented by electrode 202B, and a pair of second order neighboring stripes, also symmetrically distributed around the central stripe, and represented by electrode 202C. In particular embodiments, the spatial separation along the Y-axis between stripes is chosen in such a fashion that when biased together, the electrostatic potential lines do not leak through the gaps between adjacent stripes. For the example of FIG. 2A, FIG. 2B, and FIG. 2C, the separation between adjacent electrodes (stripes) may be set to 2 mm.

Turning to FIG. 3 there is provided a graph that depicts in a series of curves the current density of the ion beam 118 near the substrate position as a function of angle of incidence with respect to the perpendicular to plane of the substrate 124, which curves roughly represent the Ion Angular Distribution (IAD), based upon the geometry of FIGS. 2A-2C. The current density is shown for the two beamlets of ion beam 118, and is symmetrical about 0 degrees (Z-axis) in this particular illustration due to the symmetrical arrangement of the electrodes of electrode array 202, and the symmetrical arrangement of beam blocker 116A with respect to extraction aperture A. There are 6 curves shown, representing three sets of quasi-symmetrical curves, where each set corresponds to one of FIG. 2A, FIG. 2B, or FIG. 2C. The top set of curves corresponds to one variant of the configuration of FIG. 2A, with an electrostatic height shown as 8 mm, corresponding to the height of the electrode 202A, along the Y-axis, the middle curves corresponding to FIG. 2B, with an electrostatic height H 16 mm, and the bottom curves corresponding to FIG. 2C, with an electrostatic height H of 24 mm.

Note that with H=8 mm (FIG. 2A), the large majority of the current density of ion beam 118, corresponding roughly to the IAD, is between 33 degrees and 50 degrees, with the greatest density at 33 degrees. Note that with H=16 mm (FIG. 2B), the large majority of the current density of ion beam 118, corresponding roughly to the IAD, is between 40 degrees and 63 degrees, and is relatively evenly distributed in this angular range. When H=24 mm (FIG. 2C), the large majority of the current density of ion beam 118, corresponding roughly to the IAD, is between 45 degrees and 71 degrees, and is relatively evenly distributed in this angular range. Thus, by selectively coupling different combinations of electrodes of electrode array 202 to a bias voltage, the angle of incidence and IAD may be substantially changed. Thus, the ion extraction optics 140A provides the ability for in-situ variation of IAD and angle of incidence, merely by switching on/off the connections of the electrodes of electrode array 202 to a bias voltage source.

Note that the extraction assembly configuration of FIGS. 2A-2C is merely exemplary. In other embodiments, the height of the various electrodes of an electrode array in a beam blocker may be adjusted according to the desired ion angles and ion angular distribution range that is targeted for a given set of applications. Thus, the height of a central stripe (electrode) may be increased or decreased with respect to the height of outer stripes, the separation between stripes may be adjusted, and the number of stripes may also be changed. Moreover, in one embodiment, instead of a central stripe, a central pair of stripes may be symmetrically positioned about the midline of a beam blocker. An advantage of using just one central stripe is the simplicity of the design, while an advantage of using a pair of stripes is because one stripe of the pair may be coupled to a bias voltage source, while the other stripe can be read as a feed-back to check on the biasing of the pair.

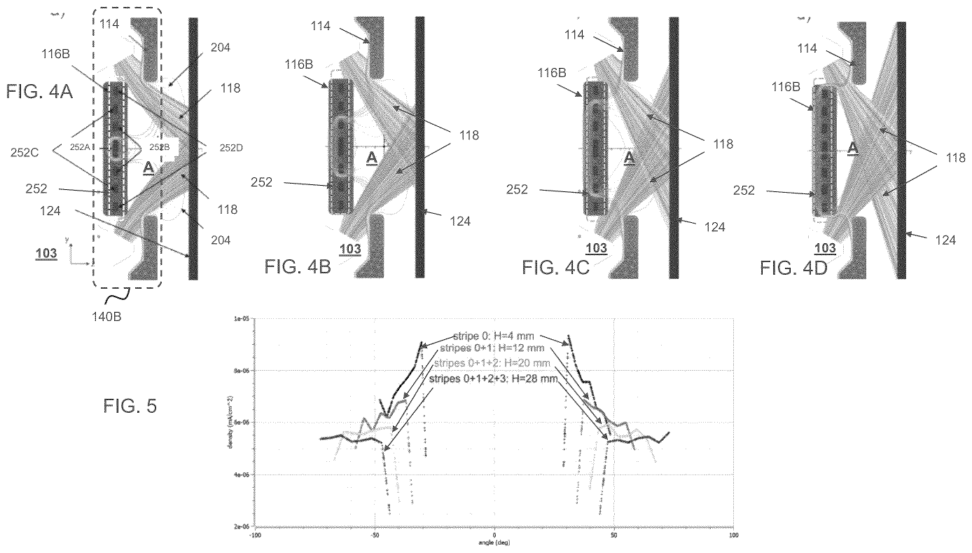

Turning to FIG. 4A, FIG. 4B, FIG. 4C, and FIG. 4D, there are shown in side cross-sectional view four different scenarios for operating a variant of the ion extraction optics 140, shown as ion extraction optics 140B. In this embodiment, a beam blocker 116B is provided with an embedded electrode array, shown as electrode array 252. The electrode array 252 includes four separate electrodes, shown as electrode 252A, electrode 252B, electrode 252C, and electrode 252D. Note that in this embodiment, the electrode 252B, electrode 252C, and electrode 252D may each be a continuous electrical stripe. In the embodiment particularly illustrated in FIGS. 4A-4D, the electrode 252A may be a central stripe, while the electrode 252B is a near-in stripe, immediately flanking both sides of electrode 252A, the electrode 252C is an intermediate stripe, flanking both sides of electrode 252B, and the electrode 252D is an outer stripe, flanking the electrode 252C on both sides. In particular, in FIG. 4A, FIG. 4B, FIG. 4C, and FIG. 4D, there is shown the results of OPERA modelling, depicting distribution of equipotential lines 204 and extracted ion beamlets shape, indicated as ion beam 118, as a function of “electrostatic height” of the electrode array 252, again for 1 kV biasing voltage, applied between substrate 124, the electrode array 252, extraction plate 114 on one hand and the plasma chamber 102 on the other hand. As shown, a plasma 103 is generated to the left of the ion extraction optics 140B in the figures. The extraction voltage between the plasma 103 contained by the chamber 102 (see FIG. 1A) is also 1 kV.

Turning to FIG. 4A, there is shown a scenario where just the electrode 202A is biased at 1 kV with respect to substrate 124, while electrode 202B and electrode 202C are not biased. Because just the electrode 252A is biased, the electrostatic height H of equipotential lines 204 along the Y-axis near the electrode array 252 is relatively less, as shown in FIG. 4A. For example, the electrostatic height H may be deemed equivalent to the height of the central stripe of electrode 252A, which value may be 4 mm. In FIG. 4B, both the electrode 252A and electrode 252B are biased at 1 kV, generating a substantially greater value of the electrostatic height H, such as 12 mm in the particular depiction. In FIG. 4C electrode 252A, and electrode 252B, electrode 252C are all biased at 1 kV generating a greater electrostatic height, such as 20 mm, while in FIG. 4D, the electrode 252A, electrode 252B, electrode 252C, and electrode 252D are all biased at 1 kV, generating a still greater value of electrostatic height H, such as 28 mm. As a result of changing the value of the electrostatic height H, the shape of ion beam 118, average angle of incidence and ion angular distribution (IAD) are changed between the configurations of FIG. 4A, FIG. 4B, FIG. 4C, and FIG. 4D, as qualitatively illustrated in the images of ion beam 118.

Turning to FIG. 5 there is provided a graph that depicts the current density of the ion beam 118 near the substrate position as a function of angle of incidence with respect to the perpendicular to plane of the substrate 124 (roughly the IAD at the substrate surface), based upon the geometry of FIGS. 4A-4D. The current density is shown for the two beamlets of ion beam 118, and is symmetrical about 0 degrees (Z-axis) in this particular illustration due to the symmetrical arrangement of the electrodes of electrode array 252, and the symmetrical arrangement of beam blocker 116B with respect to extraction aperture A. There are 8 curves shown, representing four sets of quasi-symmetrical curves, where each set corresponds to one of FIG. 4A, FIG. 4B, FIG. 4C, or FIG. 4D. The top set of curves corresponds to one variant of the configuration of FIG. 4A, with an electrostatic height shown as 4 mm, corresponding to the height of the electrode 252A, along the Y-axis, the middle curves corresponding to FIG. 4B, with an electrostatic height H 12 mm, the second-to-lower curve corresponding to FIG. 4C, with an electrostatic height H of 20 mm, and the lower curve corresponding to FIG. 4D, with an electrostatic height H of 28 mm.

Note that with H=4 mm (FIG. 4A), the large majority of the current density of ion beam 118, corresponding roughly to the IAD, is between 30 degrees and 48 degrees, with the greatest density at 30 degrees, and a mean angle of 40 degrees. Note that with H=12 mm (FIG. 4B), the large majority of the current density of ion beam 118 is between 38 degrees and 55 degrees with a mean angle of 47 degrees, and is less steeply distributed in this angular range. When H=20 mm (FIG. 4C), the large majority of the current density of ion beam 118 is between 43 degrees and 67 degrees, with a mean angle of 53 degrees, and is relatively evenly distributed in this angular range. When H=28 mm (FIG. 4D), the large majority of the current density of ion beam 118 is between 48 degrees and 73 degrees, with a mean angle of 59 degrees, and is evenly distributed in this angular range. Thus, by selectively coupling different combinations of electrodes of electrode array 252 to a bias voltage, the angle of incidence and IAD may be substantially changed. With respect to FIG. 3, these results show that the incremental tunability when switching from one “electrostatic height” to another electrostatic height can be improved by increasing the number of stripes (number of electrodes). In practical terms, the number of separate electrodes may be limited to less than 10, given the size of a beam blocker along the Y-direction, and manufacturing tolerance for forming the separate electrodes.

In additional embodiments of the disclosure, the ion angle and IAD of an ion beam may be tuned in an extraction assembly having a beam blocker with multiple electrodes, by adjusting the bias voltage/extraction voltage applied to the extraction assembly.

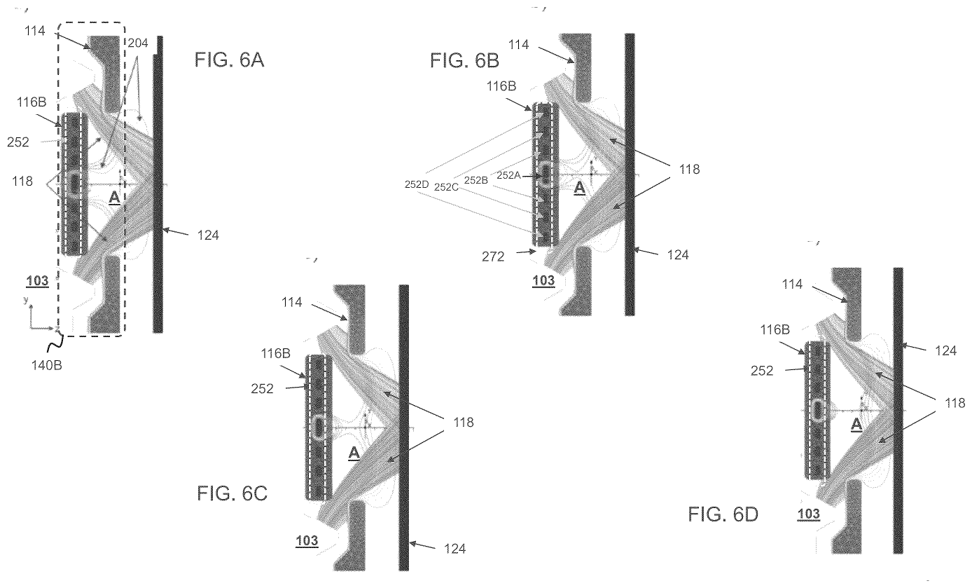

Turning to FIG. 6A, FIG. 6B, FIG. 6C, and FIG. 6D, there are shown in side cross-sectional view five different scenarios for operating ion extraction optics 140B. In particular, in FIG. 6A, FIG. 6B, FIG. 6C, and FIG. 6D, there is shown the results of OPERA modelling, depicting distribution of equipotential lines 204 and extracted ion beamlets shape, indicated as ion beam 118, as a function of bias voltage applied to the electrode array 252, where just the electrode 252A is biased. As shown, a plasma 103 is generated to the left of the ion extraction optics 140B in the figures. The plasma chamber 102 that contains plasma 103 is held at ground potential therefore the extraction voltage is equal to the biasing voltage applied to electrode 252A, extraction plate 114, and substrate 124. The bias voltage is varied from −0.75 kV, −1.0 kV, −1.25 kV, and −1.5 kV, between FIG. 6A, FIG. 6B, FIG. 6C, and FIG. 6D, respectively.

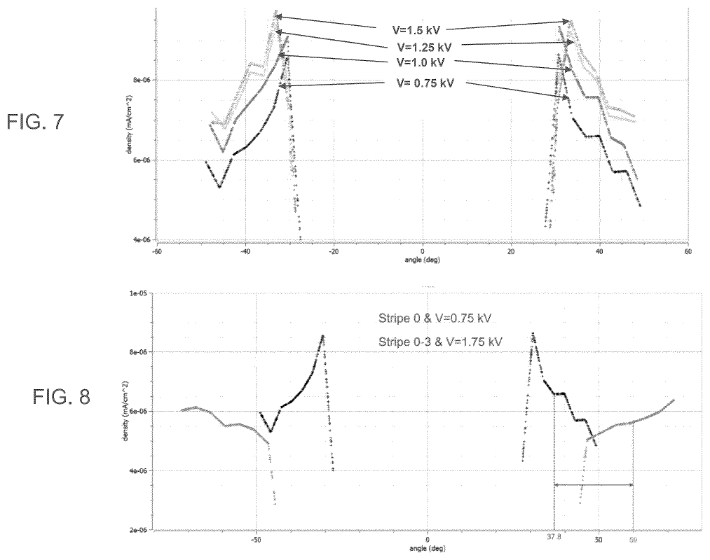

Turning to FIG. 7 there is provided a graph that depicts the current density of the ion beam 118 near the substrate position as a function of angle of incidence with respect to the perpendicular to plane of the substrate 124, based upon the geometry of FIGS. 6A-6D. The current density is shown for the two beamlets of ion beam 118, and is symmetrical about 0 degrees (Z-axis) in this particular illustration due to the symmetrical arrangement of the electrodes of electrode array 252, and the symmetrical arrangement of beam blocker 116B with respect to extraction aperture A. There are 8 curves shown, representing five sets of quasi-symmetrical curves, where each set corresponds to one of FIG. 6A, FIG. 6B, FIG. 6C, or FIG. 6D.

The results of FIG. 6A-6E, and FIG. 7 show that the mean angle and ion angular distribution may be shifted by a few degrees by changing the bias voltage applied to the electrode 252A. Of course, in the embodiments where the extraction voltage between plasma chamber 102 and substrate 124 is varied in concert with the bias voltage between electrode array 252 and substrate 124, the ion energy changes between the scenarios of FIGS. 6A-6E. Thus, this approach to adjusting ion angle may not be suitable for applications where ion energy needs to be fixed at a given value.

In additional embodiments, the mean angle and IAD for an ion beam may be adjusted by varying the electrostatic height H and bias voltage in concert with one another to achieve a targeted result. Turning to FIG. 8 there is shown a graph that depicts the current density of the ion beam 118 near the substrate position as a function of angle of incidence with respect to the perpendicular to plane of the substrate 124, based upon the ion extraction optics 140B, discussed previously. There are two sets of curves illustrated: the top set of curves corresponds to a condition where bias voltage is 0.75 kV and just the electrode 252A is biased, giving an electrostatic height of 4 mm; the bottom set of curves corresponds to a condition where the bias voltage is 1.75 kV and the entirety of electrode array 252 is biased, yielding an electrostatic height of 28 mm. In the former condition, the mean angle of incidence is 38 degrees, while in the latter, the mean angle is 59 degrees.

The aforementioned embodiments that employ an electrode array that is embedded in a beam blocker are predicated upon a manufacturing process where metal stripes are to be printed on a ceramic precursor in the green ceramic stage of formation of the beam blocker. Then, during a sintering process, the overall electrode array has to maintain the desired geometrical characteristics (height and parallelism with other stripes and with the edges of the beam blocker). In spite of the complexity, this approach has the advantage of the robustness of the blocker design. By protecting the electrode array by a relatively thick portion of the beam blocker, which component can be fabricated from a suitable combination of oxides known to be highly resistant to chemically reactive species generated in etching plasmas, the electrode array should have increased longevity in operation.

In additional embodiments of the disclosure, an extraction assembly may be provided with a beam blocker that includes an electrode array arranged on the surface of the beam blocker.

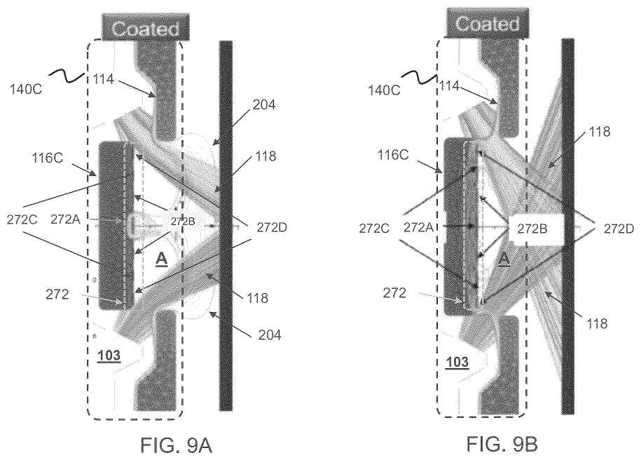

Turning to FIG. 9A and FIG. 9B, there are shown in side cross-sectional view two different scenarios for operating a variant of the ion extraction optics 140, shown as ion extraction optics 140C. In this embodiment, a beam blocker 116C is provided with a surface electrode array, or coated electrode array, shown as electrode array 272. The electrode array 272 includes four separate electrodes, shown as electrode 272A, electrode 272B, electrode 272C, and electrode 272D. Note that in this embodiment, the electrode 272B, electrode 272C, and electrode 272D may each be a continuous electrical stripe. In the embodiment particularly illustrated in FIGS. 9A-9B, the electrode 272A may be a central stripe, while the electrode 272B is a near-in stripe, immediately flanking both sides of electrode 272A, the electrode 272C is an intermediate stripe, flanking both sides of electrode 272B, and the electrode 272D is an outer stripe, flanking the electrode 272C on both sides. In particular, in FIG. 9A, FIG. 9B, there is shown the results of OPERA modelling, depicting distribution of equipotential lines 204 and extracted ion beamlets shape, indicated as ion beam 118, as a function of “electrostatic height” of the electrode array 272, again for 1 kV biasing voltage, applied between substrate 124 and the electrode array 272. The electrode array 272 is arranged with a similar geometry to electrode array 252, so that the electrostatic height H can be varied between 4 mm and 28 mm, by changing which set of electrodes are coupled to a bias voltage. In FIG. 9A, just the electrode 272A is biased, yielding H=4 mm, while in FIG. 9B, all electrodes are biased, yielding H=28 mm. As evident, the angle of incidence of the ion beam 118 is substantially increased, similarly to the results shown in FIG. 4A and FIG. 4D for electrode array 252.

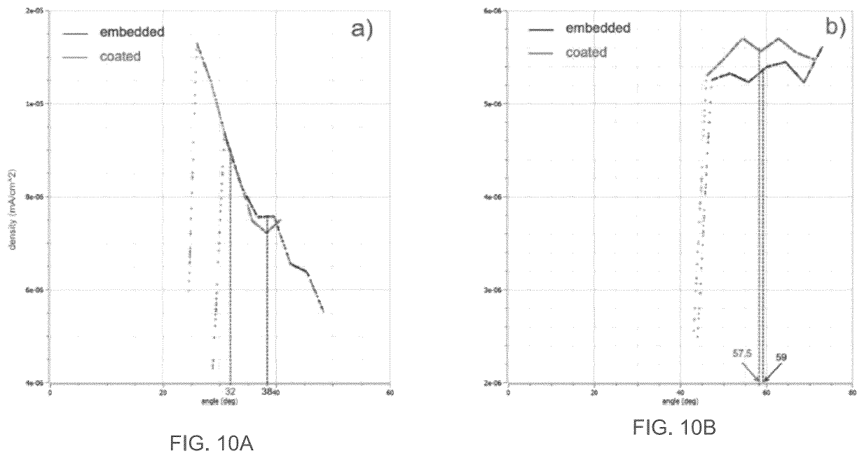

Turning to FIG. 10A there is shown a graph that depicts the current density of the ion beam 118 near the substrate position as a function of angle of incidence, for ion extraction optics 140B (electrode array 252) and ion extraction optics 140C (electrode array 272), where bias voltage is 1 kV, and just the central electrode is biased. For clarity, the current density for just one beamlet of a pair of beamlets is shown. The two curves corresponding to the two different extraction assemblies are qualitatively similar, while the mean angle of incidence is shifted lower in the case of ion extraction optics 140C by 6 degrees (38 degrees for ion extraction optics 140B as compared to 32 degrees for ion extraction optics 140C).

Turning to FIG. 10B there is shown a graph that depicts the current density of the ion beam 118 near the substrate position as a function of angle of incidence, for ion extraction optics 140B (electrode array 252) and ion extraction optics 140C (electrode array 272), where bias voltage is 1 kV, and all electrodes are biased. The two curves corresponding to the two different extraction assemblies are qualitatively similar, and the mean angle of incidence is shifted marginally lower in the case of ion extraction optics 140C by 1.5 degrees (59 degrees for ion extraction optics 140B as compared to 57.5 degrees for ion extraction optics 140C). Thus, for the same relative electrode geometry, the arrangement of electrodes on the surface of a beam blocker results in a slight shift to lower angle of incidence with respect to embedded electrodes, and a modest increase in the change in angular range available between biasing just the central electrode and biasing all electrodes.

Note that the fabrication of the beam blocker 116C presents a simpler approach than fabrication of beam blocker 116B. Namely, the body of the beam blocker 116C is sintered before electrodes are printed upon the surface, and a subsequent protective coating of a chemically resistant dielectric film is applied to the electrodes. Although, simpler from manufacturing process perspective, the encapsulating film of the beam blocker 116C may be more readily eroded, and metal stripes exposed to the chemically reactive environment during operation after a relatively lesser duration, leading to shorter component life.

Turning now to FIG. 11A, FIG. 11B, FIG. 11C, FIG. 11D, and FIG. 11E, there are shown differing views of a beam blocker 300, arranged according to embodiments of the disclosure. FIG. 11A is a rear plan view (for facing a plasma chamber), showing that the beam blocker 300 is elongated along the X-axis, and may include holes 302 for attaching to an extraction plate.

FIG. 11B is a front plan view of beam blocker 300 (for facing a process chamber), illustrating connection points, shown as connection point 304A, connection point 304B, connection point 304C, and connection point 304D. These connection points are illustrated in close-up split front plan view of FIG. 11E.

FIG. 11C presents a transparent plan view of the beam blocker 300, including an electrode array 306, which assembly is separately shown in FIG. 11D. In this embodiment, to minimize the number of electric contacts, the electrode array 306 is arranged as four separate electrodes, arranged as a single stripe along the X-axis, or a pair of stripes: a central, single stripe is shown as electrode 306A, a first order electrode, shown as electrode 306B, is arranged as a pair of stripes immediately flanking the electrode 306A, where the pair of stripes are joined at an extremity of the beam blocker 300. A second order electrode, shown as electrode 306C, is arranged as another pair of joined stripes that flanks respective stripes of electrode 306B, while an outer electrode, shown as electrode 306D, forms a pair of joined stripes that flanks respective stripes of electrode 306C. The stripes of each of these electrodes may be arranged symmetrically with respect to electrode 306A, so that the distance of each stripe of a given electrode (306B-306D) from electrode 306C is the same. In some non-limiting examples, the width of the stripes of electrode 306B, electrode 306C, and electrode 306D may be the same.

Thus, as shown in FIG. 11B, just a single connection point is used to couple a given electrode to an external voltage source: connection point 304A for electrode 306A, connection point 304B for electrode 306B, connection point 304C for electrode 306C, and connection point 304D for electrode 306D.

In operation, with the use of external biasing distribution switches, or similar components control of the “electrostatic height” is accomplished externally by switching biasing voltage on/off to the different electrodes of electrodes assembly 306.

Turning to FIG. 12A and FIG. 12B, there is shown an isometric end cross-sectional view of two variants of the beam blocker 300, shown as beam blocker 300A and beam blocker 300B, respectively. In either variant, a body 310 is provided, such as alumina, and may coated with a thin layer 312, such as a highly chemically resistant protective layer made of mixture ZrO₂ and Y₂O₃. The beam blocker 300A includes a variant of the electrode array 306, with electrode 306A1, electrode 306B1, electrode 306C1, and electrode 306D1, all embedded in body 310. The beam blocker 300B includes a variant of the electrode array 306, with electrode 306A2, electrode 306B2, electrode 306C2, and electrode 306D2, all arranged on a surface of body 310, while covered by thin layer 312.

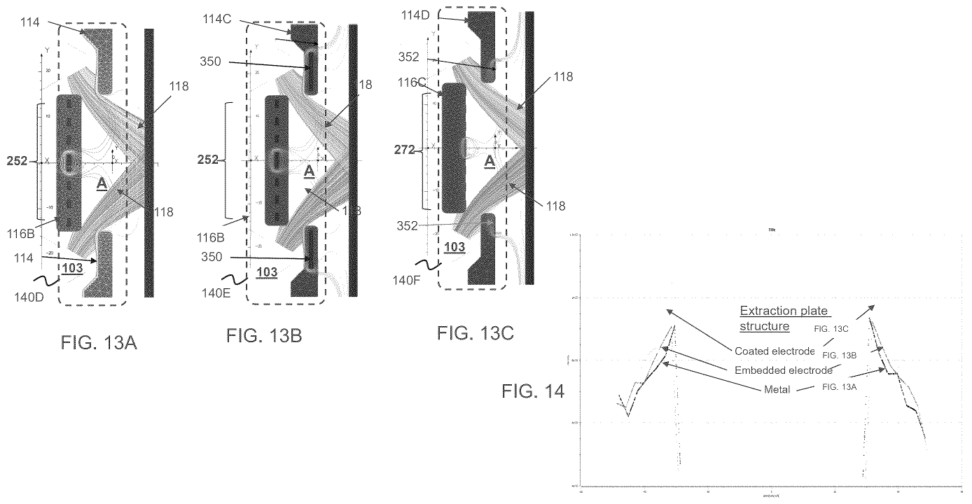

While the above-disclosed embodiments relate to extraction assemblies having selectively bias able electrodes that are distributed along a beam blocker, in additional embodiments a set of electrodes may be arranged as part of the extraction plate that flanks a beam blocker. To that end, FIG. 13A, FIG. 13B FIG. 13C depict different embodiments, where a component of the extraction plate is biased with respect to the substrate, in addition to the electrode array provided in a beam blocker.

In FIG. 13A, an ion extraction optics 140D is depicted, including the beam blocker 116B as well as a variant of extraction plate 114, described previously. In the operation scenario depicted, a 1 kV bias voltage is applied to the central electrode of electrode array 252, as well as to the extraction plate 114.

In FIG. 13B, an ion extraction optics 140E is shown, including beam blocker 116B, and an extraction plate 114C. The extraction plate 114C may be formed of a suitable ceramic material, such as alumina. A metal electrode set 350 is embedded in the extraction plate 114C, as shown, in a location immediately adjacent to the extraction aperture A, such as within a few millimeters of the edge of extraction aperture A. The metal electrode set 350 may be a single stripe circumferentially surrounding the extraction aperture A or may be separate stripes on opposite sides of the extraction aperture A. In the operation scenario depicted, a 1 kV bias voltage is again applied to the central electrode of electrode array 252, as well as to the metal electrode set 350.

In FIG. 13C, an ion extraction optics 140F is shown, including beam blocker 116C, having an electrode array 272, discussed previously, and an extraction plate 114D. The extraction plate 114D may be formed of a suitable ceramic material, such as alumina. A metal electrode set 352 is disposed on an outer surface, facing a process chamber, as shown. The metal electrode set 352 is also arranged immediately adjacent to the extraction aperture A. The metal electrode set 352 may be a single stripe circumferentially surrounding the extraction aperture A or may be separate stripes. In the operation scenario depicted, a 1 kV bias voltage is again electrode array 252, as well as to the metal electrode set 352.

Turning to FIG. 14 there is provided a graph that depicts the current density of the ion beam 118 near the substrate position as a function of angle of incidence with respect to the perpendicular to plane of the substrate 124, based upon the different extraction assemblies represented by FIG. 13A, FIG. 13B, and FIG. 13C. The current density is shown for the two beamlets of ion beam 118, and is symmetrical about 0 degrees (Z-axis) as discussed previously. There are 6 curves shown, representing three sets of quasi-symmetrical curves, where each set corresponds to one of FIG. 13A, FIG. 13B, and FIG. 13C. As shown, the three different configurations of the three different extraction assemblies generate very similar IAD results.

The present embodiments provide at least the following advantages. As a first advantage, the present ion extraction optics provide in-situ tunability of ion angular distribution for extracted ion beams, merely by using external switches or similar components to select which electrodes that are coupled to receive a bias voltage. As a further advantage, the present embodiments supply the ability to generate ion beams with relatively higher incidence angles, while still preserving the ability to generate ion beams with relatively lower incidence angles, without having to change the beam blocker, or relative positioning of a beam blocker with respect to an extraction plate.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision such modifications within the scope and spirit of the claims appended hereto.

1. A processing apparatus, comprising:
a plasma chamber;
an ion extraction optics, disposed on a side of the plasma chamber; and
a processing chamber, having a substrate holder, disposed opposite the ion extraction optics, wherein the ion extraction optics comprises:
an extraction plate, connected to the plasma chamber, and having an extraction aperture;
a beam blocker disposed adjacent to the extraction aperture, so as to define a set of extraction slits between the beam blocker and the extraction plate; and
an electrode array, disposed along the beam blocker, and comprising a plurality of electrodes that are separately connectable to a voltage source.

2. The processing apparatus of claim 1, wherein the electrode array is disposed within a body of the beam blocker.

3. The processing apparatus of claim 1, wherein the electrode array is disposed along a surface of the beam blocker, and is covered by an insulating layer.

4. The processing apparatus of claim 1, wherein the beam blocker, the extraction aperture, and the plurality of electrodes are elongated along a first direction, and wherein the plurality of electrodes are mutually spaced with respect to one another along a second direction, perpendicular to the first direction.

5. The processing apparatus of claim 4, wherein the electrode array comprises a central stripe, and a plurality of peripheral stripes that are arranged symmetrically around the central stripe.

6. The processing apparatus of claim 1, wherein the beam blocker comprises alumina, and wherein a chemically-resistant insulating layer is disposed on a surface of the beam blocker.

7. The processing apparatus of claim 3, wherein the insulating layer comprises a mixture of ZrO₂ and Y₂O₃.

8. The processing apparatus of claim 4, further comprising a set of electrodes, arranged as part of the extraction plate, along an outside of the extraction aperture.

9. The processing apparatus of claim 8, wherein the set of electrodes are arranged within a body of the extraction plate.

10. The processing apparatus of claim 8, wherein the set of electrodes are arranged along a surface of the extraction plate.

11. An ion extraction optics for a processing apparatus, comprising:
an extraction plate, having an extraction aperture that is elongated along a first direction;
a beam blocker, attachable to the extraction plate, in a region adjacent to the extraction aperture, so as to define a set of extraction slits that extend between the beam blocker and extraction plate; and
an electrode array, comprising a plurality of electrodes that are disposed along the beam blocker, and are separately connectable to a voltage source.

12. The ion extraction optics of claim 11, wherein the electrode array is disposed within a body of the beam blocker.

13. The ion extraction optics of claim 12, wherein the electrode array is disposed along a surface of the beam blocker, and is covered by an insulating layer.

14. The ion extraction optics of claim 11, wherein the beam blocker, the extraction aperture, and the plurality of electrodes are elongated along the first direction, and wherein the plurality of electrodes are mutually spaced with respect to one another along a second direction, perpendicular to the first direction.

15. The ion extraction optics of claim 14, wherein the electrode array comprises a central stripe, and a plurality of peripheral stripes that are arranged symmetrically around the central stripe.

16. The ion extraction optics of claim 11, wherein the beam blocker comprises alumina, and wherein a chemically-resistant insulating layer is disposed on a surface of the beam blocker.

17. The ion extraction optics of claim 13, wherein the insulating layer comprises a mixture of ZrO₂ and Y₂O₃.

18. The ion extraction optics of claim 14, further comprising a set of electrodes, arranged as part of the extraction plate, along an outside of the extraction aperture.

19. The ion extraction optics of claim 18, wherein the set of electrodes are arranged within a body of the extraction plate.

20. The ion extraction optics of claim 18, wherein the set of electrodes are arranged along a surface of the extraction plate.
